(19) United States
(12) Patent Application Publication
(10) Pub. No.: US 2011/0198598 A1
(43) Pub. Date: Aug. 18, 2011

(54) ORGANIC LIGHT EMITTING DISPLAY APPARATUS AND METHOD OF MANUFACTURING THE SAME

(76) Inventors: YOUNG-IL KIM, Yongin-City (KR); Tae-Yong Noh, Yongin-City (KR); Dong-Won Lee, Yongin-City (KR); Won-Pil Lee, Yongin-City (KR)

(21) Appl. No.: 13/028,565

(22) Filed: Feb. 16, 2011

(30) Foreign Application Priority Data
Feb. 16, 2010 (KR) 10-2010-0013844

(51) Int. Cl. H01L 51/52; H01L 51/56

(52) U.S. Cl. 257/59; 438/34; 257/E51.019

(57) ABSTRACT

An organic light emitting display apparatus includes a substrate, a thin film transistor (TFT) on the substrate, a first electrode on the TFT in each of a plurality of pixels, a first pixel define layer covering edges of the first electrode, the first pixel define layer including at least two layers, a second pixel define layer on the first pixel define layer, an organic emission layer on the first electrode, and a second electrode disposed to face the first electrode.

### BACKGROUND

1. Field

Example embodiments relate to an organic light emitting display apparatus and a method of manufacturing the organic light emitting display apparatus. More particularly, example embodiments relate to an organic light emitting display apparatus in which a defect in an edge area of a pixel electrode is improved and a method of manufacturing the organic light emitting display apparatus.

2. Description of the Related Art

In general, flat display devices may be classified into an emissive type and a non-emissive type. The emissive type display devices may include, for example, flat cathode ray tubes, plasma display panels (PDPs), and electroluminescent devices. The non-emissive type display devices may include liquid crystal displays (LCDs). For example, the electroluminescent devices have wide viewing angles, excellent contrast, and rapid response speeds and, thus, have recently been highlighted as next generation display devices. Such electroluminescent devices may be divided into inorganic electroluminescent devices and organic electroluminescent devices according to materials for forming an emission layer.

The organic electroluminescent device is a self-luminous display that electrically excites phosphor, e.g., fluorescent, organic compounds and emits light. The organic electroluminescent device has been highlighted as a next generation display device, which may be driven with a low voltage, easily made to be thin, has a wide viewing angle, and a rapid response speed.

The organic electroluminescent device includes an emission layer that is formed of an organic material and is interposed between an anode and a cathode. As an anode voltage and a cathode voltage are respectively applied to the anode and the cathode, holes injected from the anode move to the emission layer through a hole transport layer and electrons move from the cathode to the emission layer through an electron transport layer, so that the holes and the electrons recombine in the emission layer to form excitons.

The excitons change from an excited state to a ground state so that phosphor molecules of the emission layer radiate, thereby forming an image. In a full-color type organic electroluminescent device, pixels that emit red R, green G, and blue B colors are included to realize full color.

In such an organic electroluminescent device, a pixel define layer may be formed on both ends of the anode. A predetermined opening is formed in the pixel define layer. Then, the emission layer and the cathode are sequentially formed on the anode exposed to the outside through the opening.

### SUMMARY

Embodiments are therefore directed to an organic light emitting display apparatus and a method of manufacturing the same, which substantially overcome one or more of the problems due to the limitations and disadvantages of the related art.

It is therefore a feature of an embodiment to provide an organic light emitting display apparatus in which a defect in an edge area of a pixel electrode is improved and a method of manufacturing the organic light emitting display apparatus.

At least one of the above and other features and advantages may be realized by providing an organic light emitting display apparatus, including a substrate, a thin film transistor (TFT) on the substrate, a first electrode on the TFT in each of a plurality of pixels, a first pixel define layer covering edges of the first electrode, the first pixel define layer including at least two layers, a second pixel define layer on the first pixel define layer, an organic emission layer on the first electrode, and a second electrode disposed to face the first electrode.

The first pixel define layer may include inorganic materials and the second pixel define layer may include organic materials.

The first pixel define layer may include a first layer and a second layer, the first layer contacting the first electrode and the second layer being formed on the first layer and contacting the second pixel define layer.

The first layer may include a hydrophobic material and the second layer may include a hydrophilic material.

The first layer may be formed of a material having an etching selectivity with respect to the first electrode.

The first layer may include SiNₓ.

The second layer may include SiO₂.

The apparatus may further include a third layer between the first layer and the second layer.

The first pixel define layer may extend toward a center of the first electrode by a predetermined distance beyond the second pixel define layer.

The second pixel define layer may expose a portion of an upper surface of the first pixel define layer.

The TFT may include a semiconductor active layer formed on the substrate, a gate electrode insulated from the semiconductor active layer, and source and drain electrodes respectively contacting the semiconductor active layer.

The apparatus may further include a passivation layer interposed between the drain electrode and the first electrode.

The first pixel define layer may be directly on the TFT.

The second electrode may be formed on the second pixel define layer along the second pixel define layer.

At least one of the above and other features and advantages may also be realized by providing a method of manufacturing an organic light emitting display apparatus, the method including preparing a thin film transistor (TFT) comprising a substrate, a semiconductor active layer formed on the substrate, a gate electrode insulated from the semiconductor active layer, and source and drain electrodes respectively contacting the semiconductor active layer, forming a first electrode on the TFT so as to be electrically connected to the drain electrode of the TFT, forming a first pixel define layer comprising at least two layers on the first electrode to cover the edge of the first electrode, forming a second pixel define layer on the first pixel define layer to cover at least part of the first pixel define layer, exposing the first electrode to the outside by patterning the first pixel define layer and the second pixel define layer, forming an organic layer on the first electrode, and forming a second electrode on the second pixel define layer and the organic layer.

The forming of the first electrode on the TFT may include forming a passivation layer on the TFT, forming a predetermined opening on the passivation layer by patterning the passivation layer, coating a conductive material on the passivation layer, and patterning the conductive material to form the first electrode.

The forming of the first electrode on the TFT may include coating a conductive material on the TFT and patterning the conductive material to form the first electrode.

The first pixel define layer and the drain electrode may directly contact each other.

The first pixel define layer may include inorganic materials and the second pixel define layer may include organic materials.

The exposing of the first electrode by patterning the first pixel define layer and the second pixel define layer may include patterning the second pixel define layer to expose an upper surface of the first pixel define layer.

The forming of the first pixel define layer may include: forming a first layer contacting the first electrode; and forming a second layer on the first layer.

The first layer may include a hydrophobic material and the second layer may include a hydrophilic material.

The first layer may be formed of a material having an etching selective ratio with the first electrode.

The first layer may include SiNₓ.

The second layer may include SiO₂.

The method may further include a third layer, which functions as a buffer layer, interposed between the first layer and the second layer.

The organic layer may be formed by using inkjet printing or nozzle printing.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of an organic light emitting display apparatus according to an embodiment;

FIGS. 2 through 7 illustrate cross-sectional views of stages in a method of manufacturing the organic light emitting display apparatus of FIG. 1;

FIG. 8 illustrates a cross-sectional view of an organic light emitting display apparatus according to another embodiment; and

FIGS. 9 through 13 illustrate cross-sectional views of stages in a method of manufacturing the organic light emitting display apparatus of FIG. 8.

### DETAILED DESCRIPTION

Korean Patent Application No. 10-2010-0013844, filed on Feb. 16, 2010, in the Korean Intellectual Property Office, and entitled: “Organic Light Emitting Display Apparatus and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

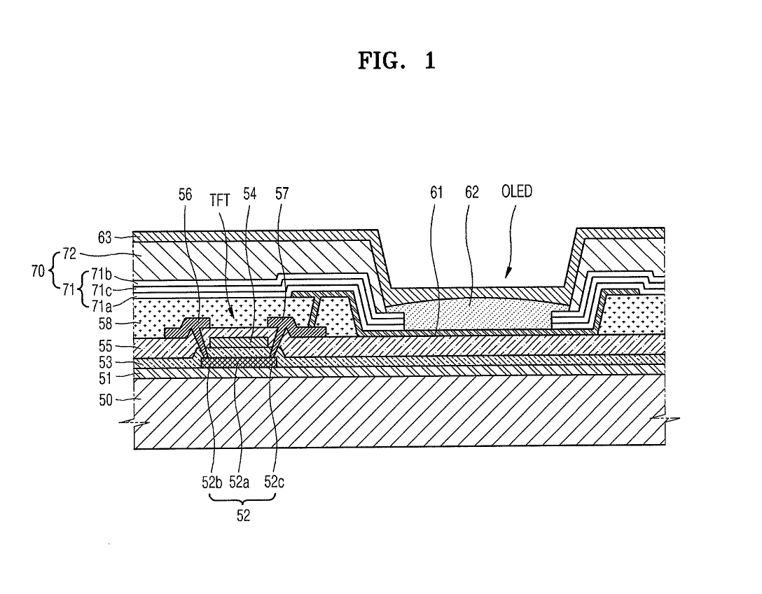

FIG. 1 illustrates a cross-sectional view of an organic light emitting display apparatus according to an embodiment. Referring to FIG. 1, a buffer layer 51 may be formed on a substrate 50, e.g., glass or plastic substrate. A thin film transistor (TFT) and an organic electroluminescent element, e.g., an organic light emitting diode (OLED), may be formed on the buffer layer 51.

The buffer layer 51 may be formed on the substrate 50, an active layer 52 formed of a semiconductor material may be formed on the buffer layer 51, and a gate insulating layer 53 may be formed to cover the active layer 52. A gate electrode 54 may be formed on the gate insulating layer 53. The gate electrode 54 may be connected to a gate line (not shown) that applies a TFT on/off signal. An interlayer insulating layer 55 may be formed to cover the gate electrode 54, and source and drain electrodes 56 and 57 may be formed on the interlayer insulating layer 55. The source and drain electrodes 56 and 57, respectively, contact source/drain areas 52b and 52c of the active layer 52 through contact holes formed in the gate insulating layer 53 and the interlayer insulating layer 55. A passivation layer 58, e.g., formed of SiO₂ and SiNₓ, may be formed on the source and drain electrodes 56 and 57.

More specifically, the active layer 52 formed on the substrate 50 may be formed of an inorganic semiconductor or an organic semiconductor. The source/drain areas 52b and 52c are doped with n-type or p-type impurities and a channel area 52a that connects the source area 52b and the drain area 52c is included in the active layer 52.

The active layer 52 may be formed of an inorganic semiconductor or an organic semiconductor. Examples of the inorganic semiconductor for forming the active layer 52 may include CdS, GaS, ZnS, CdSe, CaSe, ZnSe, CdTe, SiC, or Si. Examples of the organic semiconductor for forming the active layer 52 may include a polymer, e.g., polythiophene and a derivative thereof, poly(p-phenylene vinylene) (PPV) and a derivative thereof, polyparaphenylene and a derivative thereof, polyfluorene and a derivative thereof, polythiophene vinylene and a derivative thereof, polythiophene-hetero aromatic ring group copolymer and a derivative thereof, or low molecular weight molecule, e.g., pentacene, tetracene, oligoacene of naphthalene and derivatives thereof, alpha-6-thiophene, oligothiphene of alpha-5-thiophene and derivatives thereof, phthalocyanine containing or not containing a metal and derivatives thereof, pyromellitic dianhydride or pyromellitic diimide and derivatives thereof, perylenetetracarboxylic acid dianhydride or perylenetetracarboxylic diimide and derivatives thereof.

The active layer 52 is covered by the gate insulating layer 53 and the gate electrode 54 is formed on the gate insulating layer 53. The gate electrode 54 may be formed of a conductive metal, e.g., MoW, Al, Cr, or Al/Cu. However, example embodiments are not limited thereto. The gate electrode 54 may be formed of various conductive materials, e.g., a conductive polymer. The gate electrode 54 may be formed to cover an area corresponding to the channel area 52a of the active layer 52.

The passivation layer 58 which may protect the TFT or planarize the TFT is formed on the TFT. After a predetermined opening is formed in the passivation layer 58 to expose a portion of the interlayer insulating layer 55, a first electrode 61, e.g., an anode of the OLED, may be formed on the passivation layer 58 and the interlayer insulating layer 55 through the opening, and a pixel define layer 70 may be formed on the first electrode 61. A predetermined opening is formed in the pixel define layer 70, and an organic layer 62 is formed on the pixel define layer 70 and the first electrode 61 exposed to the outside through the opening therein. Here, the organic layer 62 includes an emission layer. Example embodiments are not limited to the structure of the organic light emitting display apparatus described above, and various structures of organic light emitting display apparatuses may be implemented.

In the organic light emitting display apparatus according to the current embodiment, the pixel define layer 70 may be formed by alternately stacking organic layers and inorganic layers, wherein the inorganic layers have a multi-layered structure, which will be described later.

An organic electroluminescent device displays predetermined image information by emitting red, green, and blue lights as current flows through the light emitting element. Such an organic electroluminescent device may include the first electrode 61, a second electrode 63, and the organic layer 62 therebetween. The first electrode 61 is connected to the drain electrode 56 of the TFT and receives a positive power voltage from the drain electrode 56, the second electrode 63 is formed to cover the entire pixels and supplies a negative power voltage, and the organic layer 62 emits light. The first electrode 61 and the second electrode 63 are insulated from each other by the organic layer 62 and respectively apply voltages of opposite polarities to the organic layer 62 to induce light emission in the organic layer 62.

The organic layer 62 may be formed of a low-molecular weight organic material or a polymer organic material. When the organic layer 62 includes the low-molecular weight organic material, the organic layer 62 may have a single or multi-layer structure including at least one of a hole injection layer (HIL), a hole transport layer (HTL), an emission layer (EML), an electron transport layer (ETL), and an electron injection layer (EIL). Examples of suitable organic materials may include copper phthalocyanine (CuPc), N,N′-di(naphthalene-1-yl)-N,N′-diphenyl-benzidine (NPB), and tris-8-hydroxyquinoline aluminum (Alq3). The low-molecular weight organic layer may be formed by performing vacuum deposition.

When the organic layer 62 includes the polymer organic layer, the organic layers 62 may have a structure including a HTL and an EML. In this case, the HTL may be formed of poly(ethylenedioxythiophene) (PEDOT), and the EML may be formed of polyphenylenevinylenes (PPVs) or polyfluorenes. The HTL and the EML may be formed by screen printing, inkjet printing, or the like. The organic layer 62 is not limited to the organic layers described above and may vary in structure.

The first electrode 61, i.e., a pixel electrode, may function as an anode and the second electrode 63 may function as a cathode. However, example embodiments are not limited thereto, and the first electrode 61 may function as a cathode and the second electrode 63 may function as an anode.

The first electrode 61 may be a transparent or reflective electrode. If the first electrode 61 is a transparent electrode, the first electrode 61 may be formed of, e.g., indium tin oxide (ITO), indium zinc oxide (IZO), zinc oxide (ZnO), or indium oxide (In₂O₃). If the first electrode 61 is a reflective electrode, the first electrode 61 may be formed by forming a reflective layer using, e.g., silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer using, e.g., ITO, IZO, ZnO, or In₂O₃ on the reflective layer.

In addition, the second electrode 63 may be a transparent or reflective electrode. If the second electrode 63 is a transparent electrode, the second electrode 63 functions as a cathode and thus is formed by depositing a metal having a low work function, e.g., lithium (Li), calcium (Ca), lithium fluoride/calcium (LiF/Ca), lithium fluoride/aluminum (LiF/Al), aluminum (Al), silver (Ag), magnesium (Mg), or a compound thereof on the surface of the organic layer 62 and forming an auxiliary electrode layer or a bus electrode line on the deposited metal by using a material for forming a transparent electrode, e.g., ITO, IZO, ZnO, or In₂O₃, or the like. If the second electrode 63 is a reflective electrode, the second electrode 63 may be formed by depositing, e.g., Li, Ca, LiF/Ca, LiF/Al, Al, Ag, Mg, or a compound thereof on the entire surface of the organic layers 62.

Hereinafter, the pixel define layer 70 included in the organic light emitting display apparatus according to the current embodiment will be described more fully. The pixel define layer 70 denotes a patterned insulating layer which accurately defines an emission area when manufacturing the organic light emitting display apparatus.

A pixel define layer of a general organic light emitting display apparatus is generally formed of a single layer including an organic material. In order to form an organic layer on the pixel define layer, a general deposition method is used. However, in order to reduce mask processes and to improve pattern precision, an inkjet printing or nozzle printing technique is currently being developed.

In an organic layer patterning process using such a printing technique, the pixel define layer is patterned to include banks defining a predetermined region on a first electrode. A soluble material or a polymer-based liquid material is injected into the banks formed by the pixel define layer and is dried to form an organic layer on the first electrode. For example, a first layer of the organic layer printed on the first electrode may be an ETL, i.e., a conductive material, e.g., PEDOT, for continuing a current flow between an emission material and the first electrode. The material for the organic layer injected into the banks may exhibit the same properties as water and a printed aspect may vary according to characteristics of the material for forming the pixel define layer. For example, when the pixel define layer is formed of a hydrophilic material, the material of the organic layer may spread beyond the first electrode to adhere to the pixel define layer. When the pixel define layer is formed of a hydrophobic material, the material of the organic layer may concentrate in a predetermined area on the first electrode defined by the pixel define layer, i.e., not adhere to the pixel define layer.

Therefore, in a structure of a general pixel define layer, the banks are formed of a hydrophobic organic pixel define layer, e.g., polyimide, acryl, or the like, and a hydrophilic first electrode, e.g., ITO. Therefore, the material for the organic layer may adhere to the first electrode without adhering to the pixel define layer. Thus, the organic material may be placed on the first electrode after the drying. However, as an edge area of the organic layer in pixels is rolled and rises during drying of the organic layer, a thickness deviation occurs in the organic layer and thereby a defect is generated in the edge area of the pixels.

In order to prevent the defect in the edge area of the pixels, the organic light emitting display apparatus according to the current embodiment may include a first pixel define layer 71 formed of an inorganic layer and a second pixel define layer 72 formed of an organic layer, wherein the first pixel define layer 71 has a multi-layer structure formed of inorganic layers. Here, the first pixel define layer 71 may be formed between the first electrodes 61, and the second pixel define layer 72 may be formed to cover edges of the first electrode 61 and the first pixel define layer 71.

In detail, in order to prevent a defect in the edge area of the pixels, a structure of a dual pixel define layer including the first pixel define layer 71 formed of inorganic layers and the second pixel define layer 72 formed of an organic layer may be implemented, so as to insulate the edge part where the defect occurs. Thus, light may not be emitted in the area where the defect occurs. The first pixel define layer 71 may be thin and exhibit insulating properties, e.g., include inorganic layers such as SiNₓ, SiO₂, or SiOₓ, thereby requiring a multi-layered structure.

In further detail, the first pixel define layer 71 may include a first layer 71a formed of SiNₓ and exhibiting hydrophobic properties, a second layer 71b formed of SiO₂ and exhibiting hydrophilic properties, and a third layer 71c therebetween. The first layer 71a may be disposed at a lower side of the first pixel define layer 71, e.g., in contact with the first electrode 61, and the second layer 71b may be disposed at an upper side of the first pixel define layer 71, e.g., in contact with the organic layer 62. As such, the first layer 71a, the third layer 71c, the second layer 71b, and the organic layer 62 may be disposed sequentially on the first electrode 61.

Accordingly, as the first layer 71a formed of SiNₓ exhibits an etching selectivity with respect to the first electrode 61 and is positioned thereon, e.g., directly thereon, the first pixel define layer 71 may be selectively etched. Also, as the second layer 71b formed of SiO₂ exhibits hydrophilic properties and is disposed to contact the organic layer 62, the first pixel define layer 71 may function as a bank. As such, since the second layer 71b is separated from the first electrode 61 at least by the first layer 71a, lack of etching selectivity between the SiO₂ of the second layer 71b and the first electrode 61, i.e., ITO, may not cause defects. Further, as the second layer 71b separates between the hydrophobic, i.e., SiNₓ, first layer 71a and the organic layer 62, defects in the pixel formation may be further reduced. The third layer 71c may function as a buffer layer for improving process margin.

The second pixel define layer 72 formed of an organic layer may be formed on the first pixel define layer 71 to cover the first pixel define layer 71. The second pixel define layer 72 may exhibit hydrophobic properties, and may define a predetermined region exposing portions of the first electrode 61 and the first pixel define layer 71. Accordingly, hydrophilic organic materials may be collected on the hydrophilic first electrode 61 and portions of the first pixel define layer 71 defined by the hydrophobic second pixel define layer 72, so pixels may be accurately placed on the first electrode 61 after drying.

According to example embodiments, a pixel define layer having an improved structure may be implemented without a change of processes. Also, the first pixel define layer 71 formed of inorganic layers may have a multi-layered structure, so that a defect in the edge area of the pixels may be significantly improved. In addition, a defective emission area may be removed to enhance optical properties.

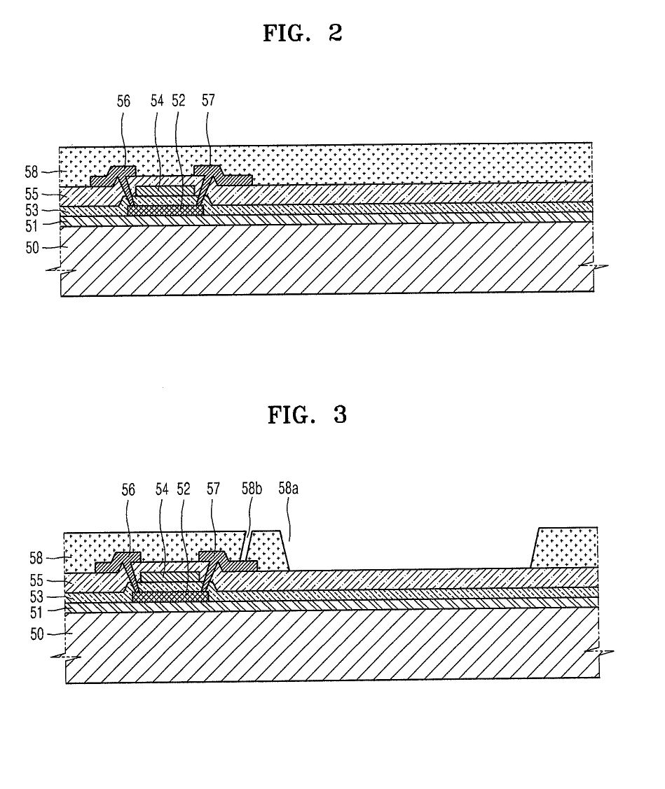

Hereinafter, a method of manufacturing the organic light emitting display apparatus according to the current embodiment will be described more fully with reference to FIGS. 2 through 7. FIGS. 2 through 7 illustrate cross-sectional views of stages in a method of manufacturing the organic light emitting display apparatus of FIG. 1.

Referring to FIG. 2, the TFT is prepared. More specifically, the buffer layer 51 may be formed on the substrate 50, the active layer 52 formed of a semiconductor material may be formed on the buffer layer 51, and the gate insulating layer 53 may be formed to cover the active layer 52. The gate electrode 54 may be formed on the gate insulating layer 53. The interlayer insulating layer 55 may be formed to cover the gate electrode 54, and the source and drain electrodes 56 and 57 may be formed on the interlayer insulating layer 55. The source and drain electrodes 56 and 57, respectively, contact source/drain areas of the active layer 52 through contact holes formed in the gate insulating layer 53 and the interlayer insulating layer 55. The passivation layer 58, e.g., formed of SiO₂ and SiNₓ, may be formed on the source and drain electrodes 56 and 57.

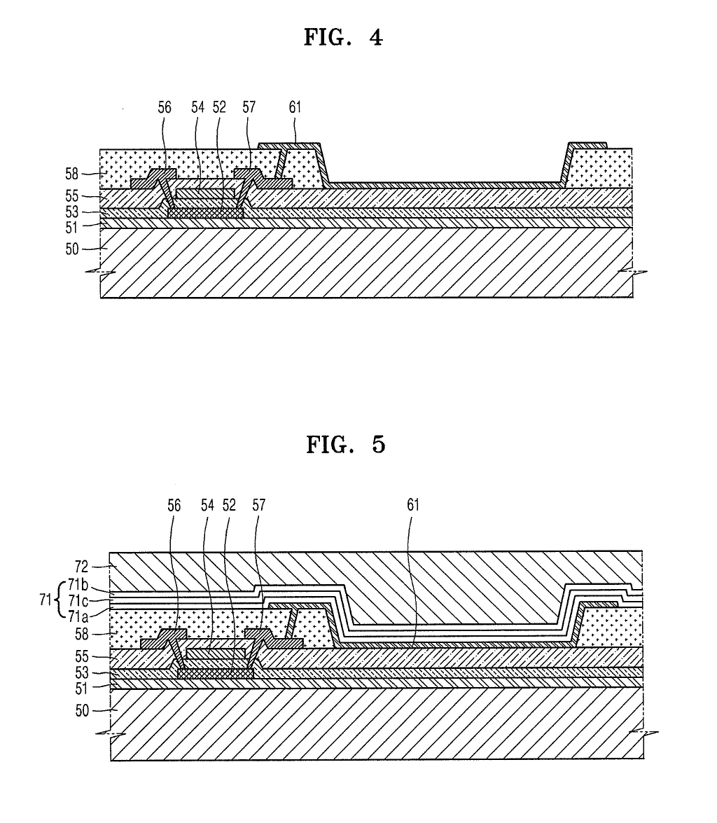

Then, referring to FIGS. 3 and 4, the first electrode 61 may be formed on the TFT. More specifically, as illustrated in FIG. 3, the passivation layer 58 may be patterned to form an opening 58a, i.e., that corresponds to a pixel area and exposes the interlayer insulating layer 55, and a contact hole 58b that exposes the drain electrode 57. Then, as illustrated in FIG. 4, a conductive material, e.g., metal or a conductive metal oxide, may be coated on the passivation layer 58 and is patterned to form the first electrode 61 in the opening 58a and the contact hole 58b.

Referring to FIG. 5, the first pixel define layer 71 having a multi-layered structure including inorganic layers may be formed on the passivation layer 58 and the first electrode 61. Next, the second pixel define layer 72 formed of an organic layer may be formed on the first pixel define layer 71.

In detail, the first layer 71a may be formed of SiNₓ to exhibit hydrophobic properties, and may be disposed to contact, e.g., directly, the first electrode 61. Then, the third layer 71c, which functions as a buffer layer for improving process margin, may be disposed on, e.g., directly on, the first layer 71a. Finally, the second layer 71b may be formed of SiO₂ to exhibit hydrophilic properties, and may be disposed on, e.g., directly on, the third layer 71c.

That is, the first layer 71a formed of SiNₓ and having an etching selectivity with respect to the first electrode 61 may be in a lower portion, i.e., a portion closer to the first electrode 61, of the first pixel define layer 71 to contact the first electrode 61. Thus, the first pixel define layer 71 may be selectively etched. Also, the second layer 71b formed of SiO₂ and having hydrophilic properties may be disposed in an upper portion, i.e., a portion closer to the organic layer 62, of the first pixel define layer 71 to contact the organic layer 62 and the second pixel define layer 72. Thus, the first pixel define layer 71 may function as a bank when depositing the organic layer 62 thereon, as will be discussed in more detail below with reference to FIG. 7.

Here, SiNₓ is provided as a material for forming the first layer 71a of the first pixel define layer 71, and SiO₂ is provided as a material for forming the second layer 71b. However, example embodiments are not limited thereto, e.g., the first pixel define layer 71 may be formed of at least one of SiO₂, SiNₓ, Al₂O₃, CuOx, Tb₄O₇, Y₂O₃, Nb₂O₅, and Pr₂O₃. Also, the first pixel define layer 71 may be formed by using, e.g., sputtering, chemical vapor deposition (CVD), or the like.

In addition, the first pixel define layer 71 is illustrated to include three layers. However, example embodiments are not limited thereto, and the first pixel define layer 71 may have a multi-layered structure including at least two layers according to requirements of a pixel define layer.

The second pixel define layer 72 may be formed of an organic layer on the first pixel define layer 71, e.g., directly on the second layer 71b. The second pixel define layer 72 may be formed of an organic material having insulating properties, e.g., polyacryl, polyimide, polyamide (PA), benzocyclobutene (BCB), and phenol resin. Here, the second pixel define layer 72 may be formed by using, e.g., spin coating, slot coating, or the like.

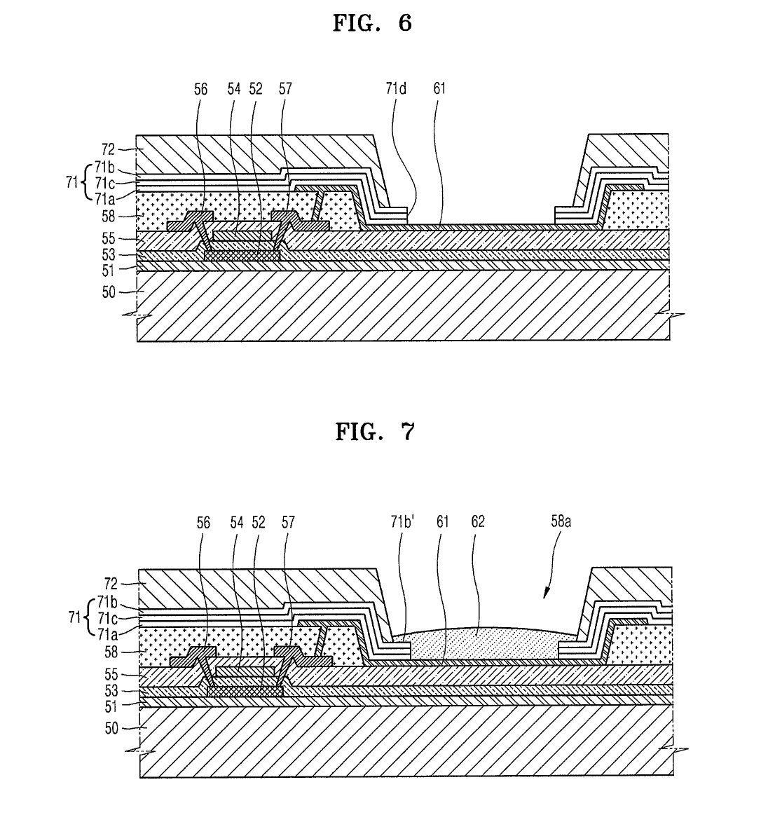

Referring to FIG. 6, the first pixel define layer 71 and the second pixel define layer 72 may be patterned to expose the first electrode 61. The first pixel define layer 71 and the second pixel define layer 72 may be patterned to expose the first electrode 61 through, e.g., photolithography. Also, the first pixel define layer 71 and the second pixel define layer 72 may be patterned by using inkjet printing.

An etching selectivity ratio between the first and second pixel define layers 71 and 72 may be adjusted, so that the first pixel define layer 71 may be projected by a predetermined degree toward the pixel area, i.e., toward a center of the first electrode 61, as compared to the second pixel define layer 72. In other words, an edge 71d of the first pixel define layer 71 may extend farther away from the TFT on the first electrode 61, as compared to the second pixel define layer 72, so the second pixel define layer 72 may not cover, e.g., may be spaced apart from, the edge of the first pixel define layer 71. As such, the second pixel define layer 72 may expose an upper surface 71b′ (FIG. 7) of the first pixel define layer 71 in the opening 58a, e.g., a predetermined length of an upper surface of the second layer 71b facing away from the first electrode 61 may be exposed on each side of the opening 58a. Accordingly, as the first pixel define layer 71 is formed to be projected by a predetermined degree toward the pixel area, as compared to the second pixel define layer 72, a combined structure of the first and second pixel define layers 71 and 72 may appropriately define a bank due to the hydrophobic second pixel define layer 72 along lateral sides of the opening 58a and the hydrophilic second layer 71b on a portion of a bottom of the opening 58a.

Then, as illustrated in FIG. 7, the organic layer 62 may be formed in the opening 58a on the first electrode 61. For example, in order to reduce mask processes and to improve pattern precision, an inkjet printing method or a nozzle printing method may be used. When the organic layer 62 is hydrophilic, the material of the organic layer 62 is deposited and maintained on, e.g., directly on, the first electrode 61 and the upper surface 71b′ of the first pixel define layer 71 without spreading on and beyond the second pixel define layer 72 due to the hydrophobic properties of the second pixel define layer 72.

Then, referring back to FIG. 1, the second electrode 63 may be formed on the organic layer 62 to complete manufacture of the organic light emitting apparatus according to the current embodiment. As discussed previously, the second electrode 63 may commonly extend across all the pixels to cover the organic layers 62 and the second pixel define layer 72.

According to the current embodiment, the organic light emitting apparatus may include a multi-layered pixel define layer having an improved structure without a change of the manufacturing processes. The first pixel define layer of the multi-layered pixel define layer may have a multi-layered inorganic structure to prevent or substantially minimize defects in the edge area of the pixels. In addition, the second pixel define layer of the multi-layered pixel define layer may have an organic structure extending from the first pixel define layer to improve deposition and accuracy of an emission area, thereby improving optical properties.

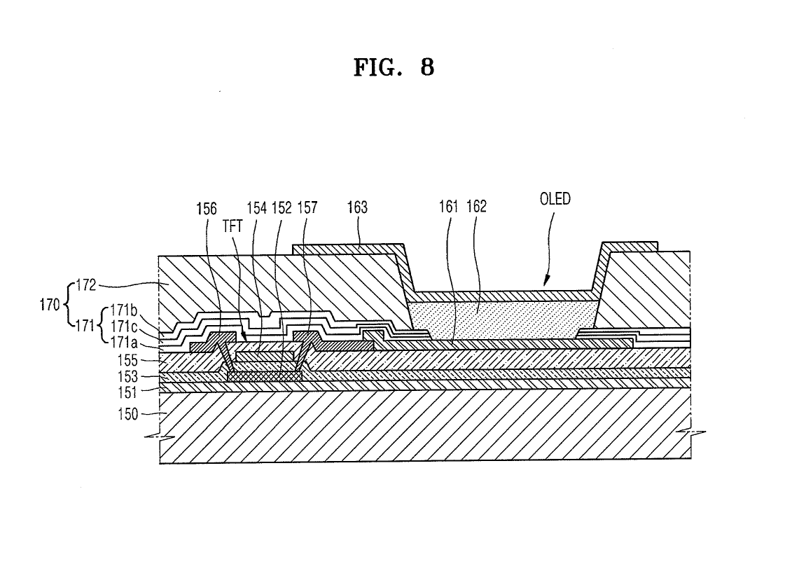

FIG. 8 illustrates a cross-sectional view of an organic light emitting display apparatus according to another embodiment. Referring to FIG. 8, a buffer layer 151 may be formed on a substrate 150, e.g., a glass or plastic substrate. A TFT and an OLED may be formed on the buffer layer 151.

The buffer layer 151 may be formed on the substrate 150, an active layer 152 formed of a semiconductor material may be formed on the buffer layer 151, and a gate insulating layer 153 may be formed to cover the active layer 152. A gate electrode 154 may be formed on the gate insulating layer 153. The gate electrode 154 may be connected to a gate line (not shown) that applies a TFT on/off signal. An interlayer insulating layer 155 may be formed to cover the gate electrode 154, and source and drain electrodes 156 and may be are formed on the interlayer insulating layer 155. The source and drain electrodes 156 and 157, respectively, contact source/drain areas 152b and 152c of the active layer 152 through contact holes formed in the gate insulating layer 153 and the interlayer insulating layer 155. Then, a first electrode 161 may be formed on the drain electrode 157 to contact the drain electrode 157.

Also, a first pixel define layer 171 may be formed on, e.g., directly on, the first electrode 161 and the TFT, wherein the first pixel define layer 171 functions as a protection layer for protecting the TFT, a planarization layer for planarizing the TFT, and a pixel define layer for defining an emission area. In addition, a second pixel define layer 172 may be formed on the first pixel define layer 171 to cover the first pixel define layer 171.

A predetermined opening may be formed in a pixel define layer 170 including the first pixel define layer 171 and the second pixel define layer 172, and an organic layer 162 may be formed on the pixel define layer 170 and the first electrode 161 exposed to the outside through the opening therein. Here, the organic layer 162 includes an emission layer. Also, a second electrode 163 may be formed on the organic layer 162 to cover the entire pixels, and may supply a negative power voltage. Example embodiments are not limited to the structure of the organic light emitting display apparatus described above, and various structures of organic light emitting display apparatuses may be implemented.

In the organic light emitting display apparatus according to the current embodiment, the pixel define layer 170 may be formed by alternately stacking organic layers and inorganic layers, wherein the inorganic layers have a multi-layered structure. In particular, the organic light emitting display apparatus according to the current embodiment is different from the organic light emitting display apparatus according to the previous embodiment in that the first pixel define layer 171 is formed on the first electrode 161 and on the TFT without forming a passivation layer on the TFT.

That is, in the organic light emitting display apparatus according to the previous embodiment, the first electrode 61 is formed on the passivation layer 58. Then, the first pixel define layer 71 having a multi-layered structure including inorganic layers and the second pixel define layer 72 formed of an organic layer are sequentially formed on the first electrode 61 and the passivation layer 58. However, in the organic light emitting display apparatus according to the current embodiment, a passivation layer is omitted, so the first define layer 171 having a multi-layered structure including inorganic layers functions as a passivation layer. That is, the first electrode 161 may be firstly formed on the drain electrode 157 to contact the drain electrode 157. Then, the first pixel define layer 171 having a multi-layered structure including inorganic layers and the second pixel define layer 172 formed of an organic layer may be sequentially formed to cover the first electrode 61 and the TFT. Then, a predetermined opening may be formed in the pixel define layer 170 so as to expose the first electrode 161. The organic layer 162 and the second electrode 163 may be formed on the pixel define layer 170.

According to the current embodiment, the first pixel define layer 171 formed of inorganic layers has a multi-layered structure so that a defect in the edge area of the pixels may be prevented. In addition, a defective emission area may be removed, so that optical properties may be improved. Furthermore, the functions of the passivation layer and the first pixel define layer may be combined with each other, so that a manufacturing process may be simple and the manufacturing costs may be reduced.

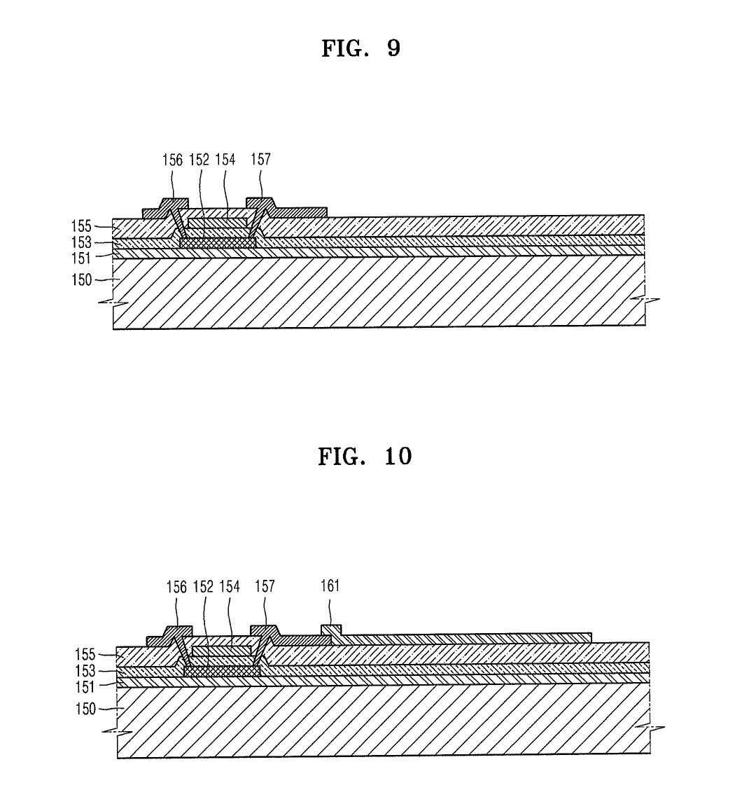

Hereinafter, a method of manufacturing the organic light emitting display apparatus according to another embodiment will be described in more detail with reference to FIGS. 9 through 13. FIGS. 9 through 13 illustrate cross-sectional views of stages in a method of manufacturing the organic light emitting display apparatus of FIG. 8.

Referring to FIG. 9, the TFT is prepared. More specifically, the buffer layer 151 may be formed on the substrate 150, the active layer 152 formed of a semiconductor material may be formed on the buffer layer 151, and the gate insulating layer 153 may be formed to cover the active layer 152. The gate electrode 154 may be formed on the gate insulating layer 153. The interlayer insulating layer 155 may be formed to cover the gate electrode 154, and the source and drain electrodes 156 and 157 may be formed on the interlayer insulating layer 155. The source and drain electrodes 156 and 157, respectively, contact source/drain areas of the active layer 152 through contact holes formed in the gate insulating layer 153 and the interlayer insulating layer 155.

Then, referring to FIG. 10, the first electrode 161 may be formed on the TFT. More specifically, a conductive material, e.g., a metal or a conductive metal oxide, may be directly coated on the source and drain electrodes 156 and 157 and the interlayer insulating layer 155, and then, may be patterned to form the first electrode 161 that contacts the drain electrode 157. Accordingly, the organic light emitting display apparatus according to the current embodiment is different from the organic light emitting display apparatus according to the previous embodiment in that a passivation layer (refer to the passivation layer 58 of FIG. 1) is not interposed between the drain electrode 157 and the first electrode 161.

Then, referring to FIG. 11, the first pixel define layer 171 having a multi-layered structure including inorganic layers may be formed on the source and drain electrodes 156 and 157, the first electrode 161, and the interlayer insulating layer 155. The second pixel define layer 172 formed of an organic layer may be formed on the first pixel define layer 171.

Firstly, a first layer 171a formed of SiNₓ having hydrophobic properties may be disposed to contact the first electrode 161. Then, a third layer 171c, which functions as a buffer layer for improving process margin, may be disposed on the first layer 171a. Finally, a second layer 171b formed of SiO₂ having hydrophilic properties may be disposed on the third layer 171c. That is, the first layer 171a formed of SiNₓ having an etching selectivity with respect to the first electrode 161 may be disposed at the lower side of the first pixel define layer 171 contacting the first electrode 161, and thus, the first pixel define layer 171 may be selectively etched. Also, the second layer 171b formed of SiO₂ having hydrophilic properties may be disposed on the first pixel define layer 171 contacting the organic layer 162 of FIG. 8, and thus, the first pixel define layer 171 may function as a bank.

Here, SiNₓ is provided as a material for forming the first layer 171a of the first pixel define layer 171 and SiO₂ is provided as a material for forming the second layer 171b. However, example embodiments are not limited thereto, and the first pixel define layer 171 may be formed of at least one of SiO₂, SiNₓ, Al₂O₃, CuOx, Tb₄O₇, Y₂O₃, Nb₂O₅, and Pr₂O₃. Also, the first pixel define layer 171 may be formed by using, e.g., sputtering, chemical vapor deposition (CVD), or the like.

In addition, the first pixel define layer 171 is illustrated as including three layers. However, example embodiments are not limited thereto, and the first pixel define layer 171 may have a multi-layered structure including at least two layers according to requirements of a pixel define layer.

The second pixel define layer 172 formed of an organic layer may be formed on the first pixel define layer 171. The second pixel define layer 172 may be formed of an organic material having insulating properties, e.g., one or more of polyacryl, polyimide, polyamide (PA), benzocyclobutene (BCB), and phenol resin. Here, the second pixel define layer 172 may be formed by using, e.g., spin coating, slot coating, or the like.

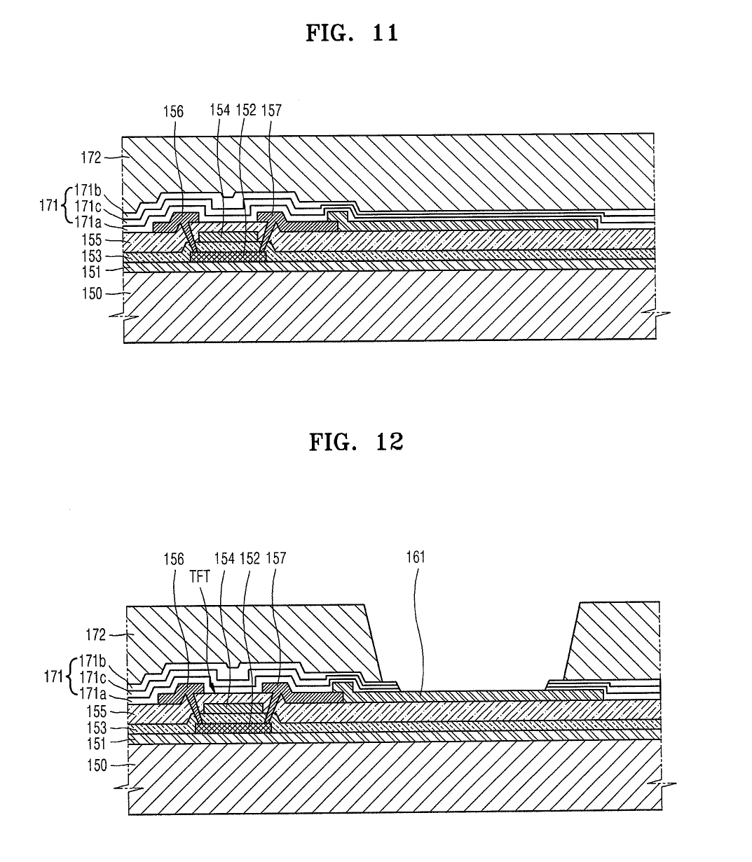

Referring to FIG. 12, the first pixel define layer 171 and the second pixel define layer 172 may be patterned to expose the first electrode 161, e.g., via photolithography. Also, the first pixel define layer 171 and the second pixel define layer 172 may be patterned by using, e.g., inkjet printing.

Here, an etching selectivity ratio is adjusted so that the first pixel define layer 171 is projected by a predetermined degree toward the pixel area, as compared to the second pixel define layer 172. That is, the second pixel define layer 172 may be formed to not cover the edge of the first pixel define layer 171. Accordingly, as the first pixel define layer 171 is formed to be projected by a predetermined degree toward the pixel area, as compared to the second pixel define layer 172, a pixel define layer may appropriately function as a bank by the hydrophobic second pixel define layer 172 and the hydrophilic second layer 171b formed on the upper most part of the first pixel define layer 171.

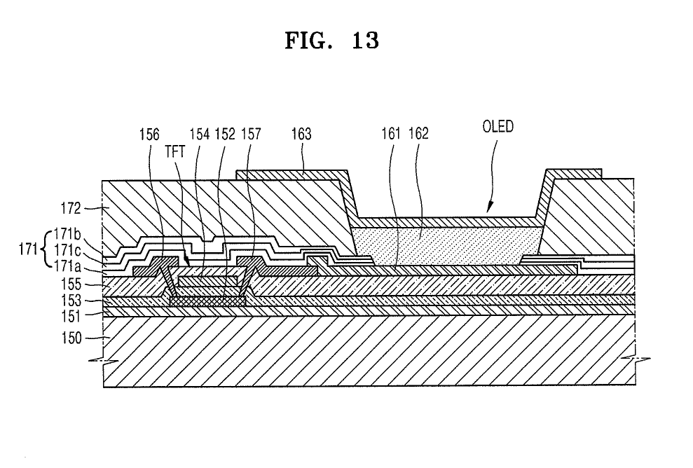

Then, as illustrated in FIG. 13, the organic layer 162 may be formed on the first electrode 161. Here, in order to reduce mask processes and to improve pattern precision, an inkjet printing or nozzle printing may be used. Then, when the second electrode 163 is formed on the organic layer 162, manufacture of the organic light emitting display apparatus of FIG. 8, according to the current embodiment, is completed.

According embodiments, the first pixel define layer 171 formed of inorganic layers has a multi-layered structure so that a defect in the edge area of the pixels may be significantly improved. In addition, a defective emission area is removed so that optical properties may be improved. Also, the functions of the passivation layer and the first pixel define layer are combined with each other, so that a manufacturing process may be simple and the manufacturing costs may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting display apparatus, comprising:
a substrate;
a thin film transistor (TFT) on the substrate;
a first electrode on the TFT in each of a plurality of pixels;
a first pixel define layer covering edges of the first electrode, the first pixel define layer including at least two layers;
a second pixel define layer on the first pixel define layer;
an organic emission layer on the first electrode; and
a second electrode disposed to face the first electrode.

2. The apparatus as claimed in claim 1, wherein the first pixel define layer includes an inorganic material, and the second pixel define layer includes an organic material.

3. The apparatus as claimed in claim 1, wherein the first pixel define layer includes a first layer and a second layer, the first layer contacting the first electrode, and the second layer being on the first layer and contacting the second pixel define layer.

4. The apparatus as claimed in claim 3, wherein the first layer includes a hydrophobic material and the second layer includes a hydrophilic material.

5. The apparatus as claimed in claim 3, wherein the first layer includes a material having an etching selectivity with respect to the first electrode.

6. The apparatus as claimed in claim 3, wherein the first layer includes SiNₓ.

7. The apparatus as claimed in claim 3, wherein the second layer includes SiO₂.

8. The apparatus as claimed in claim 3, further comprising a third layer between the first layer and the second layer.

9. The apparatus as claimed in claim 1, wherein the first pixel define layer extends toward a center of the first electrode by a predetermined distance beyond the second pixel define layer.

10. The apparatus as claimed in claim 9, wherein the second pixel define layer exposes a portion of an upper surface of the first pixel define layer.

11. The apparatus as claimed in claim 1, further comprising a passivation layer between a drain electrode of the TFT and the first electrode.

12. The apparatus as claimed in claim 1, wherein the first pixel define layer is directly on the TFT.

13. The apparatus as claimed in claim 1, wherein the second electrode is on the second pixel define layer along the second pixel define layer.

14. A method of manufacturing an organic light emitting display apparatus, the method comprising:
forming a thin film transistor (TFT) on a substrate, the TFT including a semiconductor active layer, a gate electrode insulated from the semiconductor active layer, and source and drain electrodes contacting the semiconductor active layer;
forming a first electrode on the TFT in each of a plurality of pixels, such that the first electrode is electrically connected to the drain electrode of the TFT;
forming a first pixel define layer to cover edges of the first electrode, the first pixel define layer including at least two layers;
forming a second pixel define layer on the first pixel define layer;
exposing the first electrode to the outside by patterning the first pixel define layer and the second pixel define layer;
forming an organic emission layer on the first electrode; and
forming a second electrode to face the first electrode.

15. The method as claimed in claim 14, wherein forming the first electrode includes:
forming a passivation layer on the TFT;
forming a predetermined opening in the passivation layer by patterning the passivation layer;
coating a conductive material on the passivation layer; and
patterning the conductive material to form the first electrode.

16. The method as claimed in claim 14, wherein forming the first electrode includes coating a conductive material directly on the TFT, and patterning the conductive material to form the first electrode.

17. The method as claimed in claim 16, wherein the first electrode and the drain electrode directly contact each other.

18. The method as claimed in claim 14, wherein the first pixel define layer is formed of an inorganic material, and the second pixel define layer is formed of an organic material.

19. The method as claimed in claim 14, wherein exposing the first electrode by patterning the first pixel define layer and the second pixel define layer includes patterning the second pixel define layer to expose an upper surface of the first pixel define layer.

20. The method as claimed in claim 14, wherein forming the first pixel define layer includes:
forming a first layer to contact the first electrode; and
forming a second layer on the first layer.

21. The method of claim 20, wherein the first layer includes a hydrophobic material and the second layer includes a hydrophilic material.

22. The method of claim 14, wherein the organic layer is formed by using inkjet printing or nozzle printing.
